(19) United States
(12) Patent Application Publication
(10) Pub. No.: US 2004/0169212 A1
(43) Pub. Date: Sep. 2, 2004

(54) Magnetic read only memory

(76) Inventor: Philipp J. Herget, Pittsburgh, PA (US)

Correspondence Address: Philipp Herget, Apt 5, 2015 Wendover St., Pittsburgh, PA, 15217-1938, US

(21) Appl. No.: 10/774,950

(22) Filed: Feb. 9, 2004

Related U.S. Application Data
(60) Provisional application No. 60/450,414, filed on Feb. 27, 2003.

(51) Int. Cl. H01L 29/76

(52) U.S. Cl. 257/295

(57) ABSTRACT

This invention describes a method of creating a magneto optical (MO) read only memory (ROM) storage medium using super-resolution during readout to overcome spot size limitations of the read laser. The new ROM is functionally similarly to current re-writable MO domain expansion systems such as magnetic amplifying magneto-optical systems (MAMMOS), but requires only one magnetic layer 30. Nucleation sites 34 embedded in this magnetic layer 10 enable store data, taking the place of the fields created by the storage layer which aid nucleation in a typical MAMMOS. One method of inducing these nucleation sites is by controlling the substrate shape or texture. Since this can be accomplished in the stamping process, the new ROM could be produce at a cost comparable to current ROMs while benefiting from the higher readout densities possible with domain expansion media. As an added benefit, compatibility between this ROM compatible and its more advanced re-writable MAMMOS counterpart is also possible.

### CROSS REFERENCE TO RELATED APPLICATIONS

Provisional Patent Application “MAMMOS ROM”, Ser. No. 60/450,414, filed Feb. 27, 2003

### FEDERALLY SPONSORED RESEARCH

Not Applicable

### SEQUENCE LISTING OR PROGRAM

Not Applicable

### FIELD OF INVENTION

The present invention is related to Magneto-Optical (MO) domain expansion technologies such as Magnetic Amplifying Magneto-Optical Systems (MAMMOS), and to optical Read Only Memories (ROMs).

### DESCRIPTION OF BACKGROUND

Modem optical read only memory (ROM) storage media is created by stamping pits into a plastic substrate and coating this with a reflective material such as Aluminum. By adjusting the position and length of the pits, information is encoded on the disk. Readout from these disks is accomplished by detecting these pits by the intensity variations they induce in a laser beam that is focused onto and reflected off of the surface of the disk. In later generations of optical ROM storage, higher densities are obtained by decreasing the pit dimensions and spacings. These smaller pit dimensions and spacings naturally lead to a corresponding decrease of the size of the laser spot required to readout from the disk. Although this technology has been extended for a few generations, there is a fundamental limit to how small the laser spot can be made, and thus a cap on storage densities achievable with this technology.

In the optical storage industry, re-writeable storage systems have already advanced past this fundamental spot size limit. The solution is to make a super-resolution multi-layered magnetic medium in which an upper readout layer acts to increase the resolution during readout. Since their introduction, several methods of creating super-resolution media have been developed. The most promising of these use the growth or movement of magnetic domains to detect or amplify data in the storage layer. We will refer to the media that employ these techniques as domain expansion media.

One particularly interesting domain expansion medium is the magnetic amplifying magneto-optical system (MAMMOS). In a typical MAMMOS medium, there are two layers of magnetic material. The bottom layer is called the recording layer and is used to store information. The top layer is used for readout of the information. In MAMMOS, the optical read back signal is amplified by expanding magnetic domains in this layer. A non-magnetic layer is used to provide isolation separates the two layers. FIG. 1 depicts the magnetic structure along with the external stimulus found in a typical MAMMOS system.

The mechanism which allows MAMMOS systems to read back domains much smaller than the size of the laser spot can be understood by examining the properties of the readout layer. In the readout layer, the temperature dependent magnetic properties are adjusted such that the thermal profile induced by the laser allows for detection of small domains from the recording layer.

When the readout layer is heated by the laser beam, the coercivity drops locally resulting in a coercivity profile with a minimum at the laser location. The magnetic properties of the two layers are adjusted so the fields created by the recording layer at locations with no recorded domains, are less than the coercivity of the readout layer at its lowest point. Since the fields are less than the coercivity of the readout layer at this point, no nucleation will take place.

This is illustrated in FIG. 2A-2B. In the figures, the bottom curves 22 represent the sum of the stray fields in the readout layer 18, down the center of the recorded track. These fields consist of the field created by the data in the recording layer 16 and the field generated by the external coil 20. The top curves 24 represent the coercivity of the readout layer after being heating by the laser beam 14. When the laser is located where there is no domain, the two curves don't overlap, and thus, no nucleation occurs, as is shown in FIG. 2A. However, when the laser is located where there is a domain, as shown in FIG. 2B, the extra field from the domain in the recording layer is enough to overcome the coercivity of the readout layer, and a domain will nucleate in the readout layer.

Once a domain has nucleated in the readout layer, the forces on the domain wall will cause the domain to expand in the readout layer. This expanding domain can then be detected by analyzing the laser beam reflected off the disk. Thus, MAMMOS provides super-resolution capability for reading small domain while maintaining a large readout via the domain expansion mechanism. Although this system has the super-resolution capability, and large readout signals desirable in a ROM, it is not suitable for the mass production of data needed for ROM storage for two reasons. First, due to the magnetic nature of the storage layer, the system is inherently re-writable. More importantly, the system is not a cost effective ROM simply due to the time required to write information. Writing a disk requires using the setup of FIG. 1, to scan the laser beam over the entire area to be written.

To produce a ROM, it is desirable to have a low cost method of “printing” information to the disk. In addition, it is desirable to have a technology that has a re-writable counterpart so that the reader for the ROM can also be used to record data, as is currently the case with both the CD and DVD. Finally, as stated earlier, super-resolution will be needed in order to achieve the densities required in future generations of optical disks.

One system that meets some of these requirements was recently proposed. This system, the MSR-ROM, was proposed by Birkuawa et al. in the paper “New MSR Method for High Density MSR Disks”, IEEE Transactions on Magnetics, v. 34, n. 4, pp. 1997-9, 1998, and in the U.S. Pat. Nos. 5,993,937 and 6,146,740 which are hereby incorporated in their entirety by reference. This system uses a coercivity change of one of the disks layers to store data and produce a ROM version of an MSR disk. Although this system provides a method of making a ROM with super-resolution capabilities, it has the disadvantage that it is based on MSR technology, which doesn't have the resolution and readout amplification abilities of modem domain expansion media.

### SUMMARY OF INVENTION

In this invention a different mechanism for information storage and readout from a domain expansion medium such as MAMMOS disk is proposed. The new method creates a ROM with much of the same characteristics and advantages of the original system, but with a much simpler construction. Thus the new system is suitable for fabrication of low-cost optical ROMs and allows smaller than diffraction limited bit sizes to be read back. To simplify the explanation, the method will be described here in the context of MAMMOS, but pertains to any other super-resolution medium that uses a nucleation event to detect data. Since the explanation is based on MAMMOS, we will refer to the invention as MAMMOS-ROM in the following text.

FIG. 3 shows the block diagram of a MAMMOS-ROM system. The construction of a MAMMOS-ROM differs from that of a conventional MAMMOS system, in that it consists of only one magnetic layer 30 deposited onto a substrate 32. The single magnetic layer 30 acts as both the storage and readout layer of the system.

The properties of the magnetic layer 30 are adjusted to be similar to those of the readout layer 18 in a conventional MAMMOS system. The information is encoded into this layer by creating localized decreases in the coercivity 34 in this layer using a method suitable for mass-production of disks. During readback, the regions of decreased coercivity 34 are centers of nucleation, about which a magnetic domain can expand.

FIGS. 4A-4C show the fields and coercivities during the operation of the MAMMOS-ROM system. In FIG. 4A, no laser is applied to the system. The coercivity of the readout layer 40 is thus at a constant level except for the localized dips 42 that represent the stored information. These dips in coercivity 42 are due to the nucleation sites 34 in the readout layer. At these locations, it is easier to nucleate a domain, and thus the coercivity is lowered. FIGS. 4B and 4C show the same system when a laser is focused on the medium and the external field is on. The laser causes localized heating, which further decreases the coercivity 44 at the laser location.

In FIG. 4B, the laser is centered over a nucleation site in the medium. The additional dip in coercivity at the nucleation site 46 causes the coercivity to become lower than the external field level 48. When this occurs, a nucleation and expansion will take place at this location, giving an increase in the read back signal. In FIG. 4C, the laser is positioned such that it is not located over a nucleation site in the medium. Without the additional dip in coercivity, the external field is not enough to nucleate and expand a domain in the medium.

As in a conventional MAMMOS system, these nucleation sites can be packed together and read back at bit lengths that are smaller than the laser spot size. This concept is illustrated in FIG. 5. In this figure, the operation of the system is shown when nucleation sites are packed closer together. The figure shows how the lack of a nucleation site will prevent nucleation from occurring even when neighboring nucleation sites are close by. This property gives a MAMMOS system its density advantage over conventional recording.

The rest of the MAMMOS-ROM system can be constructed to be identical to a conventional MAMMOS disk. A block diagram of how the MAMMOS-ROM can function in conjunction with a MAMMOS system is shown in FIG. 6. A laser beam is focused by the system's optics onto the disk, which is moving with respect to the beam. The reflected beam is directed to a detector and used to detect magnetization states in the disk. Finally, an external field is applied at the appropriate time to expand and collapse domains in the readout layer. This entire process is controlled by a set of controlling electronics.

The only difference between MAMMOS and the MAMMOS-ROM is that the fields provided by the storage layer in traditional MAMMOS have been replaced by nucleation sites in the MAMMOS-ROM. Since this replacement is not specific to MAMMOS, the invention will work for any super-resolution, or domain expansion medium in which a nucleation event is used to read from the disk. The storage layer of such a system is simply replaced by introducing localized nucleation sites in the other layer or layers, which represent the information to be stored.

In the case of a MAMMOS system, the ROM version can be read by using the same techniques used in MAMMOS. This includes using either conventional MAMMOS, or the more recent DPD-MAMMOS approach which is illustrated in the paper Herget et al., Jpn. J. Appl. Phys, V. 42, N. 2B, 2003, and the U.S. patent application No. 20030227831, “Domain Position Detection Magnetic Amplifying Magneto-Optical System”, which are hereby incorporated in their entirety by reference. In the case of MAMMOS, an external field is applied when the laser is over each potential bit location. If a nucleation site is present, a domain will nucleate and expand. After detection, the domain is collapsed by reversing the field. In the case of DPD MAMMOS, the field is raised before the laser arrives at each dip. When the laser arrives at the dip, expansion occurs and the nucleation site is detected. The temporal position of the detection is used to reconstruct the stored data, and the field is reversed to collapse the domain in the magnetic layer.

### BRIEF DESCRIPTION OF THE DRAWINGS

FIG. 1 is a schematic representation of an MO recording system employing super resolution

FIGS. 2A-2B are plots of the coercivity profile and the sum of the external field and readout layer fields in a MAMMOS system when the external field is on and (A) the laser is not over a recording layer domain and (B) the laser is over a recording layer domain

FIG. 3 is a schematic representation of the invention

FIGS. 4A-4C are plots of the coercivity down the center of a track in the readout layer of the invention. The plots demonstrate how nucleation occurs when the laser is on a nucleation site, and how it does not occur when it is not.

FIG. 5 shows the coercivity profile when reading out at a higher density

FIG. 6 shows a MAMMOS-ROM system illustrating the main components needed in readback.

FIGS. 7A-7C show how one particular embodiment of the invention can be manufactured.

FIGS. 8A-8C show computer simulations of fields in the a magnetic thin film with two steps.

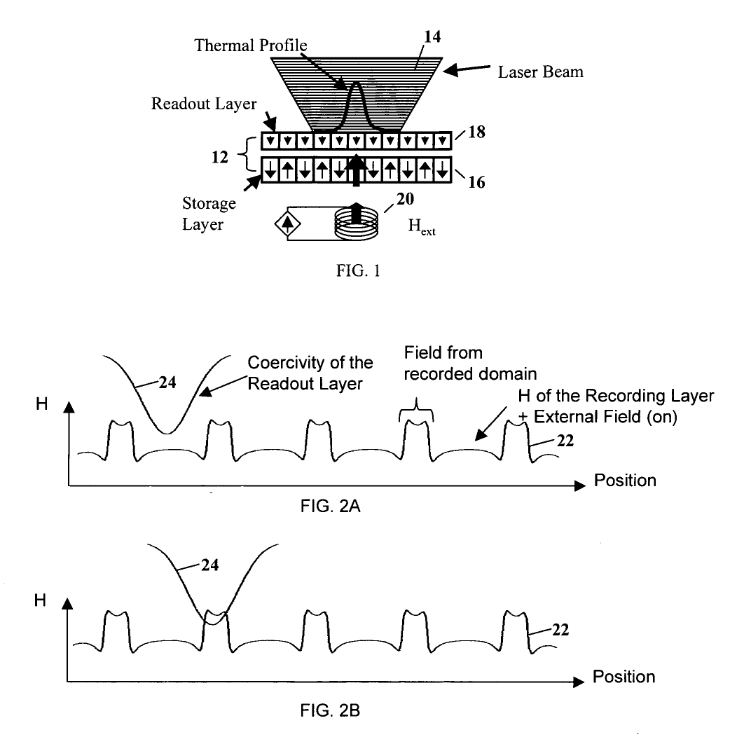

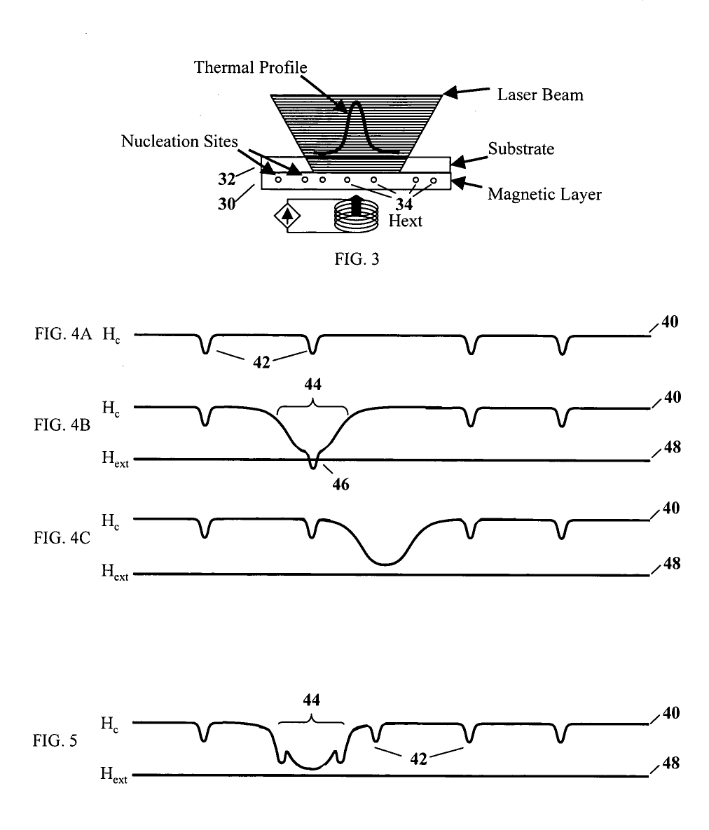

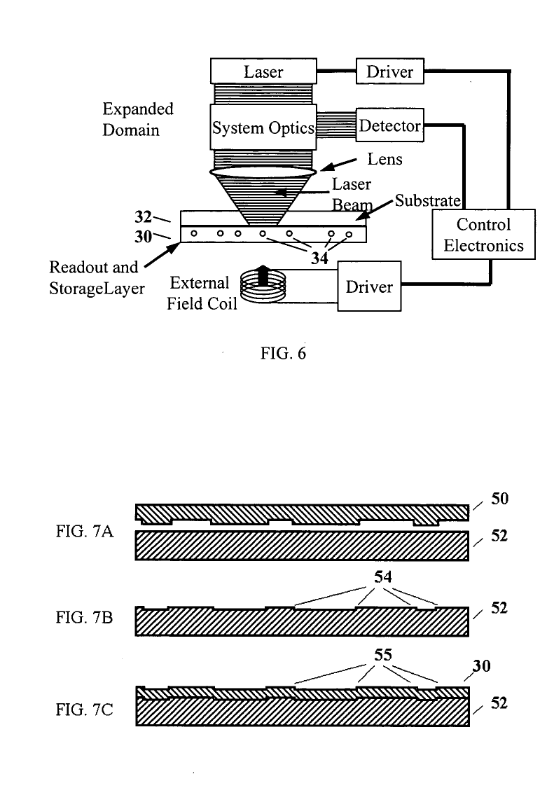

### DESCRIPTION OF PREFERRED EMBODIMENTS

To manufacture a MAMMOS-ROM, it is necessary to create nucleation sites or dips in coercivity in the magnetic layer in a pre-determined pattern. Since coercivity of a magnetic thin film is sensitive to a number of parameters such as composition, underlayer materials, underlayer textures, stresses, and shape, there is a large design space to choose from in creating coercivity dips. One of the most important design criteria however, is to make it suitable for low cost mass production.

In one particular embodiment of the invention, small steps are created in the substrate, onto which the readout layer is deposited. One of the most cost effective ways of achieving this might be through stamping or patterning. The magnetic layer, which is later deposited on top of the substrate, will take on the shape of these features. If the size and shape of the step is adjusted appropriately, it is possible to introduce a dip in the coercivity at the locations of the steps.

FIGS. 7A-7C show the steps manufacturing a MAMMOS-ROM with this process. A high precision master 50 is made with a pattern representing the information to be encoded on the ROM. FIG. 7A shows the master 50 above the substrate 52 to be stamped. After stamping, the substrate 52 contains steps 54 introduced by the stamping process, FIG. 7B. Finally, in FIG. 7C, the magnetic readout layer 30 is deposited onto the substrate. In deposition, the magnetic layer takes on the shape of the substrate and is left with steps 55 which provide the coercivity dips 42 at which nucleations can occur. This manufacturing process is very similar to the production processes used in current optical ROMs such as the digital video disc (DVD).

Computer simulations of the field patterns for a uniformly magnetized thin film with a step show that at the location of the step, an in-plane field is present. It has also been shown that in a MAMMOS system, domains will nucleate with a lower field if an in-plane component is present. This is reported in the paper “The Effect of an in-plane magnetic field on MAMMOS read-out”, by K. Mitani et al. in Japn. Appl. Magn. Soc., V 24, pp. 395-8, 2000, which is hereby incorporated in its entirety by reference. Thus a step in the magnetic film is one way to locally induce an in-plane field which decreases the effective coercivity of the readout layer.

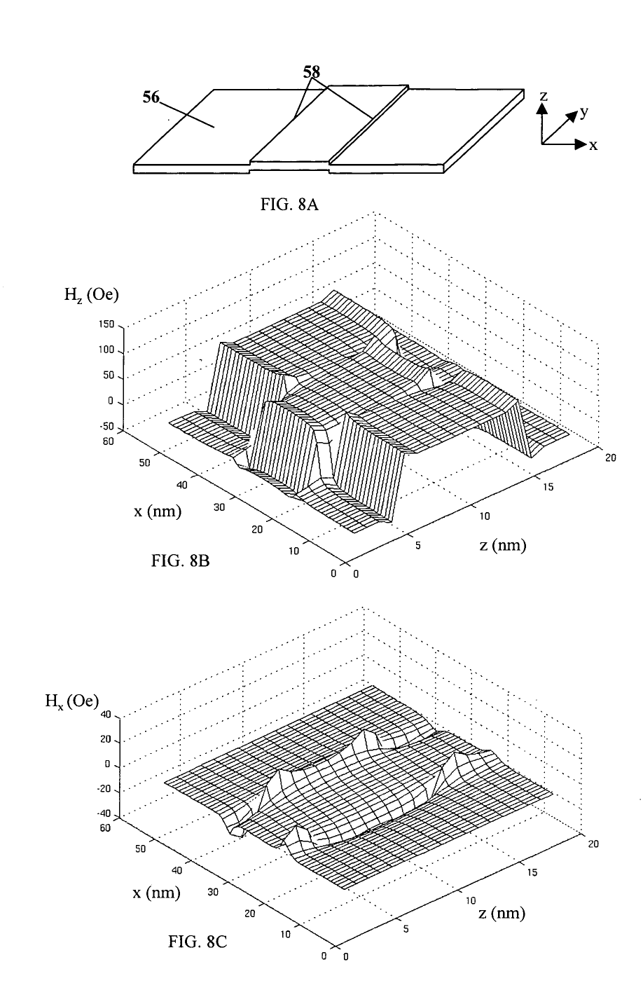

The presence of this in-plane field has been shown computationally. Computer simulations of a uniformly magnetized thin film with two steps are shown in FIGS. 8A-8C. FIG. 8A shows a diagram of the structure that was simulated. The structure consists of a uniformly magnetized thin magnetic film 56 with two steps 58 in it. These steps 58 in the simulated material are a model of the steps 55 in FIG. 7C, which can be used to create a nucleation site in the MAMMOS-ROM. FIG. 8B shows a plot of the z component of the calculated field inside the film shown in FIG. 8A for a cross section of the film in the x-z plane. The coordinate system for the calculations is given on the right size of FIG. 8A. FIG. 8C gives the x component of the field in the same plane and along the same direction as in FIG. 8B. It is clear from FIGS. 8B and 8C that at the edges in the film, an additional in-plane component to the field inside the film is present, while the z component of the field stays relatively uniform. It is this in-plane component which promotes nucleation at the edge.

In addition to the shape affect on coercivity, it is well know that the coercivity of a magnetic layer can depend strongly on the surface roughness of the underlayer. This was also shown by Birkuawa et al. in the paper “New MSR Method for High Density MSR Disks”, IEEE Transactions on Magnetics, v. 34, n. 4, pp. 1997-9, 1998, and in the U.S. Pat. Nos. 5,993,937 and 6,146,740. In another embodiment of the invention, the nucleation sites could be created by changing the roughness of the underlayer by some means such as stamping. Through the stamping process, it may also be possible to alter the surface characteristic, giving an alternate mechanism that can be used to induce a coercivity dip in the stamping process.

One of the other possibilities for lowering the coercivity of a magnetic layer to change the composition. If, for example, the percentage of Gd in TbGdFeCo is increased, the coercivity of the MO layer is decreased. This could be accomplished through ion implantation, which can be applied selectively by placing a mask over a flat substrate with an MO recording layer, and bombarding it with ions.

The method presented utilizes current technology to make a low-cost, high-density optical ROM memory. From the perspective of the disk drive, the ROM medium is functionally identical to the system it is designed from, such as the MAMMOS-ROM, which is similar to the MAMMOS disk. As a result the ROM can be read in the same drive as the re-writable disk. If the nucleation sites are implemented by placing steps in the readout layer film, the manufacturing techniques needed to make this ROM are very similar to processes currently used to make ROMs. These ROMS could be manufactured with similar costs and overheads as the ROMs on the market today. Thus, this technology enables the manufacture of low-cost, high-density ROMs, which can be used in MAMMOS read/write drives. In addition, from a disk manufacturing standpoint, migration to the new ROM format would be simple.

### CONCLUSION

In conclusion, a method of making a single layer domain expansion ROM has been proposed. The magnetic layer in this ROM acts as both the storage and readout layers in an MAMMOS disk. Information is stored in the layer by creating nucleation sites, which may consist of local decreases in the coercivity of the readout layer. This has a similar effect as the field normally applied from the recording layer of an MAMMOS disk. Reading can be accomplished by employing the same methods normally used in MAMMOS. Since the manufacturing of such a disk is simple and similar to current optical ROMs, MAMMOS-ROMs can be produced at low cost and without much overhead when migrating from the old technology.

What is claimed is:

1. A storage medium comprising:
a. a substrate,
b. a magnetic layer, and
c. a means of selectively introducing a plurality of nucleation sites into said magnetic layer,
whereby said nucleation sites represent the information to be stored.

2. The storage medium of claim 1 wherein said nucleation sites are introduced into said magnetic layer by creating features on said substrate.

3. The storage medium of claim 1 wherein said nucleation sites are introduced into said magnetic layer by creating steps on said substrate.

4. The storage medium of claim 1 wherein said substrate has a surface with a texture, and said texture is selectively altered to introduce said nucleation sites into said magnetic layer.

5. The storage medium of claim 1 wherein said magnetic layer is a magneto-optical thin film.

6. A method of storing information in a magneto-optical medium comprising: creating nucleation sites in said medium to store the information.

7. The method of claim 6 wherein said nucleation sites are introduced into said magnetic layer by creating features on said substrate.

8. The method of claim 6 wherein said nucleation sites are introduced into said magnetic layer by creating steps on said substrate.

9. The method of claim 6 wherein said substrate has a surface with a texture, and said textured is selectively altered to introduce said nucleation sites into said magnetic layer.

10. A method of storing information in and reading information from a magnetic layer comprising:
a. creating a plurality of nucleation sites at predetermined locations in said magnetic layer, and
b. heating said storage layer at a selected location to detect said nucleation sites in said magnetic layer,
whereby said nucleation sites represent the information to be stored and
whereby heating said storage layer causes a magnetic domain to nucleation when a nucleation site is present under said selected location.

11. The method of claim 10 wherein said nucleation sites are introduced into said magnetic layer by creating features on said substrate.

12. The method of claim 10 wherein said nucleation sites are introduced into said magnetic layer by creating steps on said substrate.

13. The method of claim 10 wherein said substrate has a surface with a texture, and said textured is selectively altered to introduce said nucleation sites into said magnetic layer.

14. A method of fabricating a domain expansion medium comprising: depositing a single magnetic layer in which said magnetic layer's properties are used to both store and read back information.

15. The method of claim 14 wherein said magnetic properties store information by containing localized nucleation sites.

16. The method of claim 14 wherein said nucleation sites are introduced into said magnetic layer by creating features on said substrate.

17. The method of claim 14 wherein said nucleation sites are introduced into said magnetic layer by creating steps on said substrate.

18. The method of claim 14 wherein said substrate has a surface with a texture, and said textured is selectively altered to introduce said nucleation sites into said magnetic layer.
